(19) United States
(12) Patent Application Publication
(10) Pub. No.: US 2024/0194602 A1
(43) Pub. Date: Jun. 13, 2024

(54) BACKSIDE POWER DISTRIBUTION NETWORK SUBSTRATE USING A LATTICE MATCHED ETCH STOP LAYER

(71) Applicant: International Business Machines Corporation, Armonk, NY (US)

(72) Inventors: Alexander Reznicek, Troy, NY (US); Tsung-Sheng Kang, Ballston Lake, NY (US); Daniel Schmidt, Niskayuna, NY (US); Ruilong Xie, Niskayuna, NY (US)

(21) Appl. No.: 18/080,029

(22) Filed: Dec. 13, 2022

(51) Int. Cl. H01L 23/528; H01L 21/02; H01L 23/485

(52) U.S. Cl. CPC H01L 23/5286; H01L 21/02381; H01L 21/02428; H01L 21/02483; H01L 21/02513; H01L 21/02532; H01L 21/0259; H01L 23/485

(57) ABSTRACT

A semiconductor structure includes a lattice matched etch stop layer disposed on a silicon substrate layer. The lattice matched etch stop layer is lattice matched to the silicon substrate layer. The semiconductor structure further includes an epitaxial silicon layer disposed on the lattice matched etch stop layer, a front-end-of-the-line device layer disposed on the epitaxial silicon layer, a back-end-of-the-line device layer disposed on the front-end-of-the-line device layer, and a carrier wafer disposed on the back-end-of-the-line device layer.

### BACKGROUND

Generally, semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. Within an interconnect structure, conductive vias can run perpendicular to the substrate and conductive lines can run parallel to the substrate.

### SUMMARY

Illustrative embodiments of the present application include techniques for use in semiconductor manufacture. In an illustrative embodiment, a semiconductor structure comprises a lattice matched etch stop layer disposed on a silicon substrate layer. The lattice matched etch stop layer is lattice matched to the silicon substrate layer. The semiconductor structure further comprises an epitaxial silicon layer disposed on the lattice matched etch stop layer, a front-end-of-the-line device layer disposed on the epitaxial silicon layer, a back-end-of-the-line device layer disposed on the front-end-of-the-line device layer, and a carrier wafer disposed on the back-end-of-the-line device layer.

According to another exemplary embodiment, a semiconductor structure comprises an epitaxial silicon layer free of crystalline defects, and a backside power distribution network disposed on the epitaxial silicon layer.

According to yet another exemplary embodiment, a method, comprises forming a lattice matched etch stop layer on a silicon substrate layer, epitaxially growing a silicon layer on the lattice matched etch stop layer, forming a front-end-of-the-line device layer on the epitaxially grown silicon layer, forming a back-end-of-the-line device layer on the front-end-of-the-line device layer, and forming a carrier wafer on the back-end-of-the-line device layer to form a semiconductor structure. The lattice matched etch stop layer is lattice matched to the silicon substrate layer.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 depicts a cross-sectional view of a semiconductor structure at a first-intermediate fabrication stage, according to an illustrative embodiment.

FIG. 2 depicts a cross-sectional view of a semiconductor structure at a second-intermediate fabrication stage, according to an illustrative embodiment.

FIG. 3 depicts a cross-sectional view of a semiconductor structure at a third-intermediate fabrication stage, according to an illustrative embodiment.

FIG. 4 depicts a cross-sectional view of a semiconductor structure at a fourth-intermediate fabrication stage, according to an illustrative embodiment.

FIG. 5 depicts a cross-sectional view of a semiconductor structure at a fifth-intermediate fabrication stage, according to an illustrative embodiment.

FIG. 6 depicts a cross-sectional view of a semiconductor structure at a sixth-intermediate fabrication stage, according to an illustrative embodiment.

FIG. 7 depicts a cross-sectional view of a semiconductor structure at a seventh-intermediate fabrication stage, according to an illustrative embodiment.

FIG. 8 depicts a cross-sectional view of a semiconductor structure at an eighth-intermediate fabrication stage, according to an illustrative embodiment.

### DETAILED DESCRIPTION

This disclosure relates generally to semiconductor devices, and more particularly to a backside power distribution network (BSPDN) substrate formation using a lattice matched etch stop layer on a silicon substrate and methods for their fabrication. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Various techniques may be used to remove a silicon substrate when forming a backside power distribution network. For example, silicon germanium (SiGe) may be used as an etch stop layer. However, a sufficiently thick SiGe layer is necessary and exceeds the critical thickness of the SiGe, thereby leading to the generation of defect. If the thickness of the SiGe is below the critical thickness then the SiGe will not be thick enough to compensate for the silicon thickness variation caused by wafer grinding. In addition, there is limited etch selectivity between the SiGe etch stop layer and silicon substrate. As another example, using highly n-doped silicon as an alternative has similar issues. In particular, the high doping levels needed to achieve a desired etch selectivity will lead to defects in the crystalline material. In addition, even if one could accomplish low defectivity using, for example, epitaxial Si:P with 2−3×10²¹ cm⁻³ doping, the etch selectivity between the two materials is not sufficient when a relatively thick silicon layer (multiple microns) needs to be removed.

Accordingly, illustrative embodiments described herein overcome the foregoing drawbacks. Advantages of the illustrative embodiments include that deposition of a layer of a lattice matched etch stop layer such as a relatively thin layer of an epitaxial oxide onto a silicon substrate using, for example, molecular beam epitaxy (MBE), is a straight forward process and allows for subsequent growth of a device quality epitaxial silicon such as a relatively thick layer of device quality epitaxial silicon. Other advantages include that the lattice matched etch stop layer exhibits a superb etch selectivity against crystalline silicon, and can be made to have the same lattice constant as the silicon substrate, resulting in relatively little to no crystalline defects in the subsequently grown silicon. These defects can act as traps and affect, for example, the turn-on of the device (transistor), as well as the stability and mobility of the device. Thus, the illustrative embodiments allow for an improved semiconductor structure.

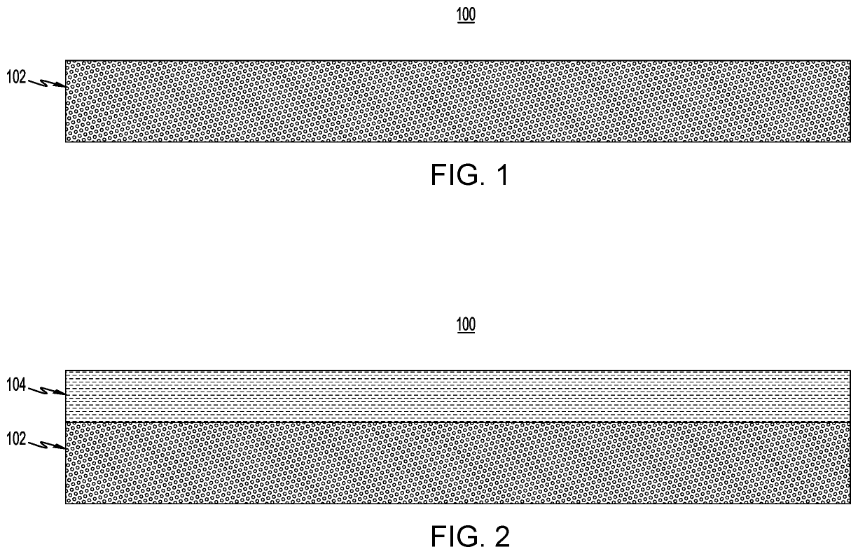

Referring now to the drawings in which like numerals represent the same of similar elements, FIGS. 1-8 illustrate various processes for fabricating a semiconductor structure. Note that the same reference numeral (100) is used to denote the semiconductor structure through the various intermediate fabrication stages illustrated in FIGS. 1-8. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1-8 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1 illustrates a cross-sectional view of a semiconductor structure 100 with a starting silicon substrate 102.

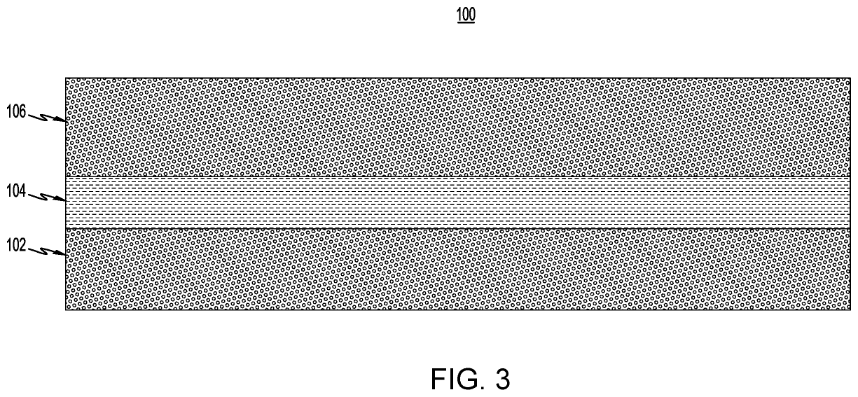

FIG. 2 shows semiconductor structure 100 at a second-intermediate fabrication stage. During this stage, a lattice matched etch stop layer 104 is formed on the silicon substrate 102. In a non-limiting illustrative embodiment, the lattice matched etch stop layer 104 is lattice matched to the silicon substrate 102. The term “lattice matched” as used herein shall be understood to mean that the lattice constant of the lattice matched etch stop layer material discussed below can be varied arbitrarily so that it is equal to, or an integral multiple of the lattice constant of the silicon substrate. In illustrative embodiments, the lattice matched etch stop layer 104 may comprise a mixed rare earth material such as a mixed rare earth oxide. In addition, the mixed rare earth oxide is lattice-matched to the silicon substrate 102. For example, in one embodiment, lattice matched etch stop layer 104 may comprise a mixed rare earth oxide on silicon, with the mixed rare earth oxide being single crystal and lattice-matched to silicon. In one illustrative embodiment, a mixed rare earth oxide is a metastable (LaₓY₁₋ₓ)₂O₃ alloy, where x is 0.33, a range of from 0.32 to 0.34 is less preferred. This alloy, at x is 0.33, can be lattice-matched to silicon and will crystallize in the cubic structure. That is, in its most basic form, the mixed rare earth oxide is grown on a silicon substrate.

In illustrative embodiments, a lattice constant of the mixed rare earth oxide may be twice a lattice constant of the silicon substrate. In illustrative embodiments, a lattice constant of the mixed rare earth oxide may be twice a lattice constant of silicon. In illustrative embodiments, a mixed rare earth material includes oxides which can be used herein in terms of looking at the lattice constants and matching them so that they could match silicon. Suitable mixed rare earth oxides include, for example, samarium (e.g., (SmₓY₁₋ₓ)₂O₃), cerium (CeₓY₁₋ₓ)₂O₃), gadolinium (LaₓGd₁₋ₓ)₂O₃), gadolinium oxide and europium oxide (e.g., (GdₓEu₁₋ₓ)₂O₃), etc.

In illustrative embodiments, the mixed rare earth oxide comprises a ternary mixed rare earth oxide. In illustrative embodiments, the mixed rare earth oxide comprises a rare earth cubic ternary oxide. In illustrative embodiments, the mixed rare earth oxide will have a majority amount of one rare earth oxide compound, to ensure the resulting ternary mixed rare earth oxide formed on the silicon substrate has a cubic lattice, and will also have a minority amount of another rare earth oxide. A majority amount as used herein should be understood to mean at least about 55% of the ternary mixed rare earth oxide compound. A minority amount as used herein should be understood to mean no more than about 45% of the ternary mixed rare earth oxide compound. Examples of the majority compounds include, but are not limited to, Eu₂O₃, Gd₂O₃, Tb₂O₃, Dy₂O₃, Ho₂O₃, Er₂O₃, Tm₂O₃, Yb₂O₃, Lu₂O₃, Y₂O₃, etc. Examples of the minority compounds include, but are not limited to, La₂O₃—, Ce₂O₃, Pr₂O₃—, Nd₂O₃, Pm₂O₃—, Sm₂O₃, etc.

To be lattice matched with silicon substrate 102, the ternary mixed rare earth oxide should have a substantially exact percentage of each compound. By substantially exact percentage of each compound means an exact percentage plus or minus one percent. Representative examples of rare earth oxides matching silicon include La—Y—O with 33% lanthanum, 68.8% gadolinium oxide with 31.2% europium oxide, 91.3% gadolinium oxide with 8.7% lanthanum oxide, 58.5% erbium oxide with 41.2% neodymium oxide, 62.6% erbium oxide with 37.4% lanthanum oxide, etc.

The lattice matched etch stop layer 104 can be formed using conventional epitaxial growth techniques such as molecular beam epitaxy (MBE), so that an epitaxial film of good quality may be grown on silicon substrate 102 by depositing the mixed rare earth material such as (LaₓY₁₋ₓ)₂O₃. In an illustrative embodiment, lattice matched etch stop layer 104 can have a thickness ranging from about 10 nanometers (nm) to about 500. In an illustrative embodiment, lattice matched etch stop layer 104 can have a thickness ranging from about 50 nm to about 150 nm.

In one embodiment, the lattice matched etch stop layer 104 has a different etch rate than the silicon substrate 102. In another embodiment, the lattice matched etch stop layer 104 has a different polishing rate than the silicon substrate 102.

FIG. 3 shows semiconductor structure 100 at a third-intermediate fabrication stage. During this stage, silicon layer 106 is grown on lattice matched etch stop layer 104. In an illustrative embodiment, silicon layer 106 can be grown on lattice matched etch stop layer 104 using conventional epitaxial growth techniques such as MBE, so that an epitaxial film of good quality may be grown on lattice matched etch stop layer 104. By epitaxially growing silicon layer 106 on the lattice matched etch stop layer 104 that is lattice matched to the silicon substrate 102, the newly grown silicon layer 106 will have its natural lattice constant and be defect free or free of crystalline defects. In an illustrative embodiment, silicon layer 106 can have a thickness ranging from about 5 nm to about 500 nm. In an illustrative embodiment, lattice matched etch stop layer 104 can have a thickness ranging from about 50 nm to about 200 nm.

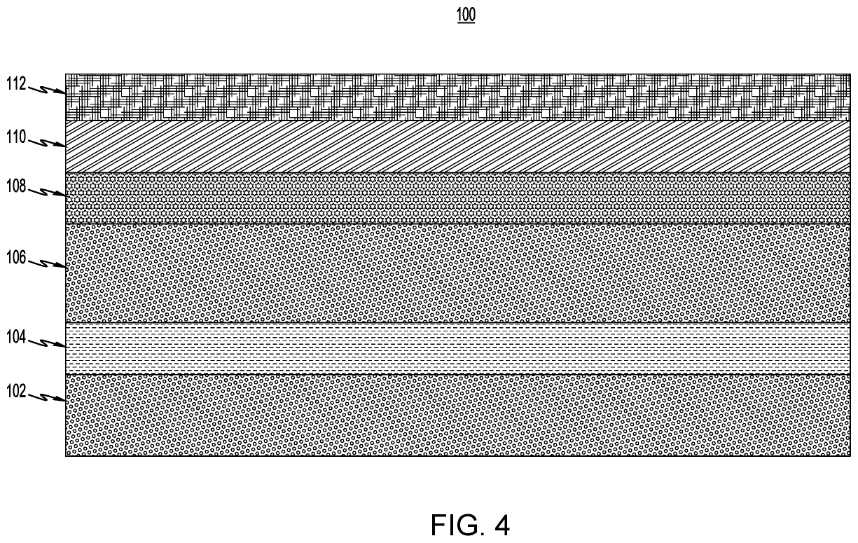

FIG. 4 shows semiconductor structure 100 at a fourth-intermediate fabrication stage. During this stage, FEOL device layer 108 is formed on silicon layer 106. FEOL device layer 108 can include various device components for the semiconductor structure 100, such as, for example, active transistors, like complementary metal oxide semiconductor (CMOS) circuits, bipolar junction transistor (BJT) transistors, passive device like resistors, capacitors, diodes, etc. FEOL device layer 108 can also include a wiring scheme that is disposed on both sides of the device layer (e.g., middle-of-the-line (MOL) interconnects to wire the devices to BEOL, and source/drain sacrificial placeholders to enable backside contact formation later to wire the devices to backside interconnect).

BEOL device layer 110 is then formed on FEOL device layer 108. BEOL device layer 110 can include, for example, a lower frontside BEOL layer containing various BEOL interconnect structures including, for example, insulating layers (dielectrics), metal levels, and/or via levels. In illustrative embodiments, the lower frontside BEOL layer may only be used for signal routing, without any power distribution network.

BEOL device layer 110 can also include, for example, an upper frontside BEOL layer containing various BEOL interconnect structures including, for example, insulating layers (dielectrics), metal levels, via levels and bonding sites. In illustrative embodiments, the upper frontside BEOL layer may comprise only signal wiring. In illustrative embodiments, the upper frontside BEOL layer may comprise both signal wiring and wires for power delivery.

Carrier wafer 112 is then bonded to BEOL device layer 110. The carrier wafer 112 may be formed of materials similar to that of the silicon substrate 102, and may be formed over the BEOL device layer 110 using a wafer bonding process, such as dielectric-to-dielectric bonding.

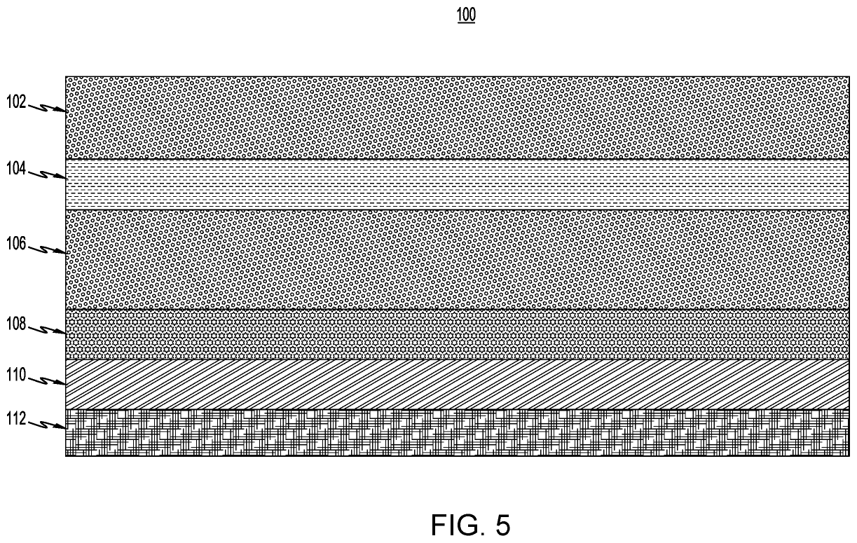

FIG. 5 shows semiconductor structure 100 at a fifth-intermediate fabrication stage. During this stage, using the carrier wafer 112, the semiconductor structure 100 is “flipped” over so that the backside of the silicon substrate 102 (i.e., the back surface) is facing up for backside processing as shown.

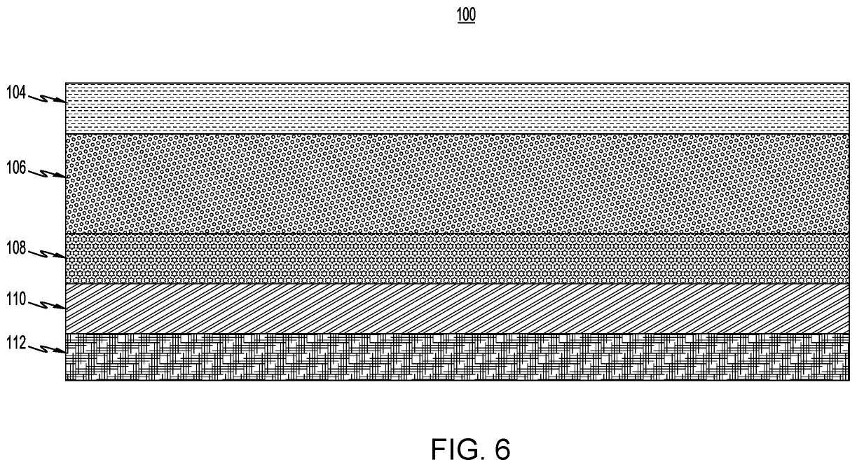

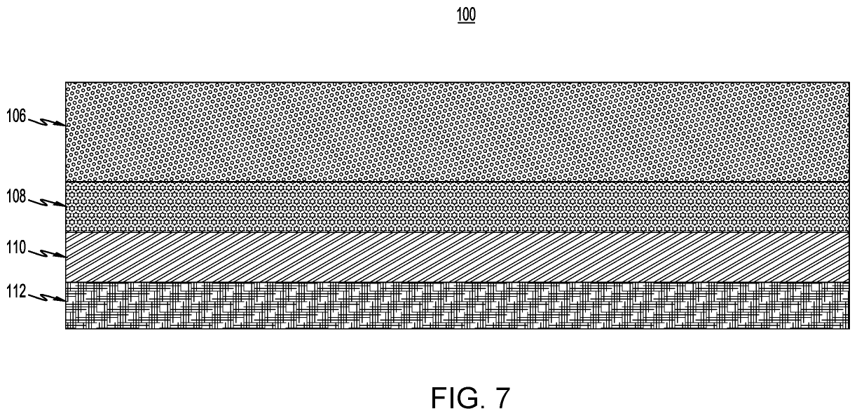

FIG. 6 illustrates semiconductor structure 100 at a sixth-intermediate fabrication stage. During this stage, silicon substrate 102 is removed from the backside using, for example, a wet or dry etch to selectively remove silicon substrate 102 until the lattice matched etch stop layer 104 is reached.

FIG. 7 illustrates semiconductor structure 100 at a seventh-intermediate fabrication stage. During this stage, the lattice matched etch stop layer 104 is selectively removed using, for example, a wet or dry etch to selectively remove lattice matched etch stop layer 104 until silicon layer 106 is reached.

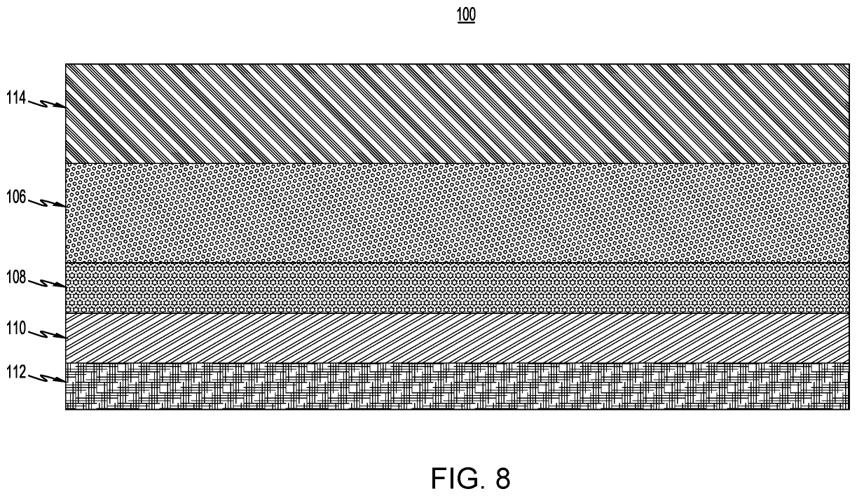

FIG. 8 illustrates semiconductor structure 100 at an eighth-intermediate fabrication stage. During this stage, a backside power distribution network 114 is formed on silicon layer 106 to provide power to a number of semiconductor devices. In illustrative embodiments, the backside power distribution network 114 has fewer metal levels (about 5 or so) than the BEOL (more than 10). Backside power distribution network 114 is formed over the silicon layer 106 thereby allowing the silicon layer 106 to be the substrate for the backside power distribution network 114.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a lattice matched etch stop layer disposed on a silicon substrate layer, wherein the lattice matched etch stop layer is lattice matched to the silicon substrate layer;
an epitaxial silicon layer disposed on the lattice matched etch stop layer;
a front-end-of-the-line device layer disposed on the epitaxial silicon layer;
a back-end-of-the-line device layer disposed on the front-end-of-the-line device layer; and
a carrier wafer disposed on the back-end-of-the-line device layer.

2. The semiconductor structure according to claim 1, wherein the lattice matched etch stop layer comprises an epitaxial oxide layer.

3. The semiconductor structure according to claim 2, wherein the epitaxial oxide layer comprises a layer of a mixed rare earth oxide, the mixed rare earth oxide being single crystal and lattice-matched to the silicon substrate layer.

4. The semiconductor structure according to claim 3, wherein the mixed rare earth oxide comprises a compound having a chemical formula (AₓB₁₋ₓ)₂O₃, wherein A represents a first rare earth element and B represents a second rare earth element.

5. The semiconductor structure according to claim 3, wherein the mixed rare earth oxide comprises (LaₓY₁₋ₓ)₂O₃ and x is 0.33.

6. The semiconductor structure according to claim 5, wherein the epitaxial silicon layer is free of crystalline defects

7. The semiconductor structure according to claim 3, wherein the mixed rare earth oxide comprises a ternary mixed rare earth oxide.

8. The semiconductor structure according to claim 1, wherein the epitaxial silicon layer is free of crystalline defects.

9. The semiconductor structure according to claim 1, wherein the lattice matched etch stop layer comprises an epitaxial oxide layer and the epitaxial silicon layer is free of crystalline defects.

10. The semiconductor structure according to claim 9, wherein the epitaxial oxide layer comprises a layer of a mixed rare earth oxide, the mixed rare earth oxide being single crystal and lattice-matched to the silicon substrate layer.

11. The semiconductor structure according to claim 10, wherein the mixed rare earth oxide comprises a compound having a chemical formula (AₓB₁₋ₓ)₂O₃, wherein A represents a first rare earth element and B represents a second rare earth element.

12. The semiconductor structure according to claim 1, wherein the lattice matched etch stop layer has a thickness ranging from about 10 nanometers (nm) to about 500 nm and the epitaxial silicon layer has a thickness ranging from about 5 nm to about 500 nm.

13. The semiconductor structure according to claim 1, wherein the lattice matched etch stop layer has a different etch rate than the silicon substrate layer.

14. The semiconductor structure according to claim 1, wherein the lattice matched etch stop layer has a different polishing rate than the silicon substrate layer.

15. A semiconductor structure, comprising:
an epitaxial silicon layer free of crystalline defects; and
a backside power distribution network disposed on the epitaxial silicon layer.

16. The semiconductor structure according to claim 15, further comprising a front-end-of-the-line device layer disposed on the epitaxial silicon layer.

17. The semiconductor structure according to claim 16, further comprising a back-end-of-the-line device layer disposed on the front-end-of-the-line device layer.

18. The semiconductor structure according to claim 17, further comprising a carrier wafer disposed on the back-end-of-the-line device layer.

19. A method, comprising:
forming a lattice matched etch stop layer on a silicon substrate layer, wherein the lattice matched etch stop layer is lattice matched to the silicon substrate layer, epitaxially growing a silicon layer on the lattice matched etch stop layer;
forming a front-end-of-the-line device layer on the epitaxially grown silicon layer;
forming a back-end-of-the-line device layer on the front-end-of-the-line device layer; and
forming a carrier wafer on the back-end-of-the-line device layer to form a semiconductor structure.

20. The method according to claim 19, further comprising:
flipping the semiconductor structure such that the silicon substrate layer is a topmost layer;
removing the silicon substrate layer to expose the lattice matched etch stop layer;
removing the lattice matched etch stop layer to expose the epitaxially grown silicon layer; and
forming a backside power distribution network on the epitaxially grown silicon layer.
